(19) United States
(12) Patent Application Publication
(10) Pub. No.: US 2005/0095763 A1
(43) Pub. Date: May 5, 2005

(54) Method of forming an NMOS transistor and structure thereof

(76) Inventors: Srikanth B. Samavedam, Austin, TX (US); James K. Schaeffer, Austin, TX (US); Philip J. Tobin, Austin, TX (US); Bikas Maiti, Austin, TX (US); Joseph C. Mogab, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/696,346

(22) Filed: Oct. 29, 2003

(51) Int. Cl. H01L 21/336; H01L 21/8234; H01L 21/4763

(52) U.S. Cl. 438/197; 438/592

(57) ABSTRACT

In one embodiment, metal boride (MBₓ), metal carbide (MCₓ), metal carbo-nitrides (MCₓN_{y}), metal boro-carbide (MBₓC_{y}), metal boro-nitride (MBₓN_{y}) or metal boro-carbo-nitride (MBₓC_{y}N_{z}), wherein the metal is a transition metal (Group III-XII of the periodic chart) may be suitable as NMOS gate electrode materials. Such materials, such as TaC and LaB₆, can be formed to have work functions that are within approximately 4-4.3 eV, which is desirable for NMOS transistors. In addition, the amount of carbon or nitrogen can be adjusting the amount of carbon or nitrogen in the precursor to achieve a predetermined metal work function.

### FIELD OF THE INVENTION

The invention relates generally to semiconductor devices, and more specifically, to metal gates.

### BACKGROUND

Polysilicon has traditionally been used as a gate electrode for MOS transistors. The polysilicon electrode is typically doped either P-type or N-type to match the doping of the source and drain regions in CMOS (complementary metal-oxide-semiconductor) technology. The polysilicon electrode needs to be highly and uniformly doped. High temperature processes are performed to diffuse and activate the dopants down to the interface of the polysilicon electrode and a gate dielectric. As device dimensions shrink, however, problems exist with using polysilicon as the gate electrode. The dopants from the polysilicon, specifically, boron, can penetrate the gate dielectric during a high temperature process and cause threshold voltage variation. If the high temperature process is not performed, however, the dopants are more likely to reside away from the gate dielectric. Hence, there will be an area of the gate electrode that is not doped. This dopant depletion effect, also referred to as poly-depletion effect, will act as an additional capacitance in series with gate dielectric capacitance and substrate capacitance. In other words, the capacitance from the poly-depletion effect will undesirably increase the effective oxide thickness of the transistor. The poly-depletion effect was not a significant effect in older technology, because the thickness of the poly-depletion thickness was small compared to the gate dielectric effective thickness. In addition, polysilicon is disadvantageous to be used with high dielectric constant materials. High dielectric constant (high-k) materials are replacing silicon dioxide as a gate dielectrics to reduce electrical leakage through the gate dielectric and stand-by power dissipation in scaled CMOS devices. As used herein, a high-k material is one that has a dielectric constant greater than silicon dioxide.

One solution is to use a material including a metal as the gate electrode. For optimum functionality of a transistor, a low threshold voltage (Vₜ) is desired, which can be achieved by having the work function of the NMOS and PMOS transistor close to the conduction and valence bands of a silicon substrate, respectively. For example, a desirable work function for PMOS is approximately 4.9-5.2 eV and for NMOS is approximately 4-4.3 eV. Finding materials with the desirable work function for NMOS transistors is difficult. The problem is especially difficult when a metal gate is desirable in conjunction with a high dielectric constant (hi-k) gate dielectric. Due to Fermi level pinning most metals typically have a work functions away from the silicon conduction and valence band edges and are therefore not suitable for either NMOS or PMOS devices. For example, when hafnium oxide (HfO₂), a high dielectric constant material, is used as a gate dielectric most metal gate materials have a work function close to the charge neutrality level of HfO₂ of approximately 4.5 eV. Therefore, a need exists for suitable metals to be used as gate electrodes for NMOS and PMOS devices, especially in conjunction with high dielectric constant materials used as gate dielectrics.

### BRIEF DESCRIPTION OF THE DRAWINGS

The present invention is illustrated by way of example and is not limited by the accompanying figures, in which like references indicate similar elements.

FIGS. 1-5 illustrate a cross-sectional view of a semiconductor device during processes used to fabricate an integrated dual-metal gate CMOS transistor in accordance with an embodiment of the present invention; and

FIG. 6 illustrates a cross-sectional view of an NMOS transistor in accordance with an embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

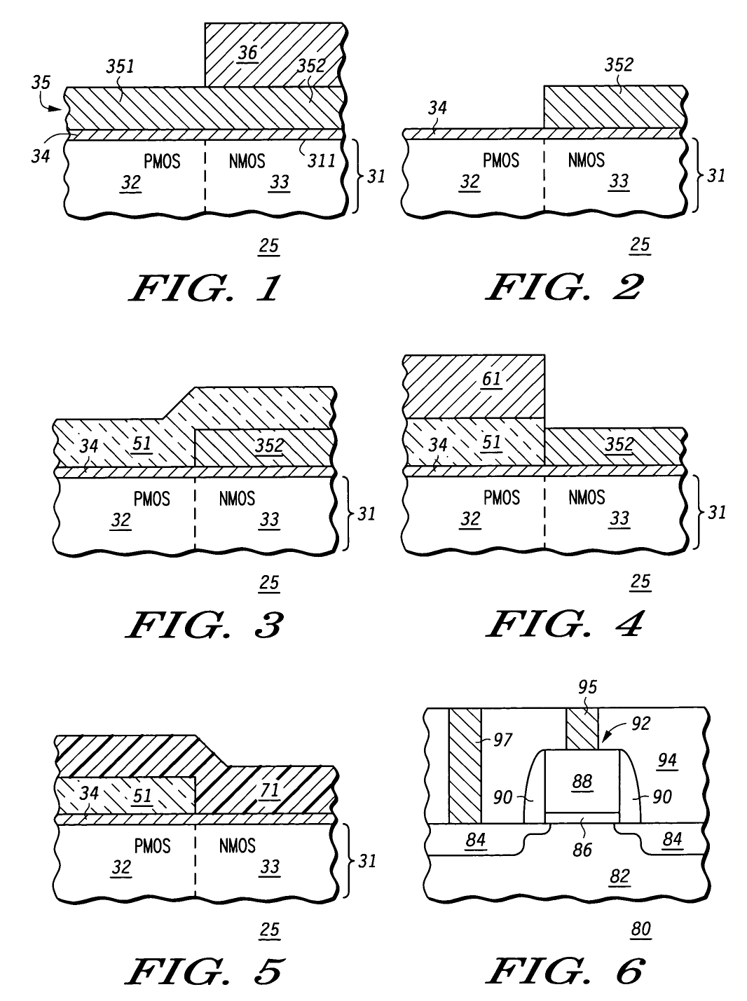

FIGS. 1 through 5 illustrate one embodiment of fabricating a dual-metal gate CMOS transistor. It should be understood, however, that the invention described herein is not confined in applicability to the fabrication of CMOS devices. The fabrication process described here obviates potential damage to the underlying gate dielectric by protecting the gate dielectric with a sacrificial layer, such as SiO₂, for example.

Directing attention now to FIG. 1 a semiconductor substrate 31 is provided that will be used to form a first semiconductor device 25. The semiconductor substrate 31 may be any semiconductor material, such as silicon, gallium arsenide, silicon on insulator (SOI), the like, and combinations of the above. Within the semiconductor substrate 31, PMOS area 32 and NMOS area 33 are formed using conventional processes, such as doping processes. As used herein, the PMOS area 32 is the area where a PMOS transistor will be formed and the NMOS area 33 is the location where an NMOS transistor will be formed. In the PMOS area 32 a p-type transistor will be formed and in the NMOS area 33 an n-type transistor will be formed. Subsequent to substrate doping, an n-well (not shown) is formed in the semiconductor substrate 31 to accommodate PMOS area 32; and a p-well (not shown) is formed to accommodate NMOS area 33. Ordinarily, in the context of a twin-well design such as is suggested here, the n-well is selectively implanted in the area of the semiconductor substrate 31 where PMOS area 32 will be formed; and the p-well is selectively implanted in the area of the semiconductor substrate 31 where the NMOS area 33 will be formed. In one embodiment, the n-well may itself be enclosed within a tub (not shown) having p-type conductivity. In another embodiment, the semiconductor substrate 31 may include a lightly doped epitaxial layer that is formed over heavily doped bulk silicon. That is, the semiconductor substrate 31 may include a P⁻ epitaxial layer formed in P⁺ bulk silicon. As is well known, n-type conductivity areas may be formed by implantation with phosphorous or arsenic and p-type conductivity areas may be formed by implantation with boron or antimony.

In practice, the PMOS and NMOS areas of the device are separated by an isolation structure (not shown). Various isolation techniques are known and include LOCOS isolation, shallow trench isolation, deep trench isolation, etc. Depiction and description of isolation techniques is not deemed edifying here and has therefore been omitted for the sake of clarity and simplicity.

As shown in FIG. 1, a gate dielectric material 34 is formed on a surface 311 of the semiconductor substrate 31. The gate dielectric material 34 may be any insulating material such as silicon dioxide. In a preferred embodiment, the gate dielectric material 34 is a high dielectric constant material (high-k material), meaning the gate dielectric material 34 has a dielectric constant greater than that of silicon dioxide. High-k materials are advantageous because they exhibit a relatively high dielectric constant (k), thereby enabling the deposition of a thicker gate dielectric layer without adversely affecting the physical and electrical characteristics of the deposited dielectric layer. In one embodiment, the high-k material may be a metal oxide (MeOx) oxides or oxynitrides of zirconium, hafnium, aluminum, lanthanum, strontium, titanium, silicon, the like, and combinations thereof. In one embodiment, the metal oxide is hafnium oxide (HfO₂).

Next, a sacrificial layer 35 is formed over the gate dielectric material 34, in one embodiment, to a thickness of approximately 50 to 500 Angstroms (5-50 nanometers). The sacrificial layer 35 may be silicon dioxide (SiO₂) that has been deposited in accordance with known techniques, such as chemical vapor deposition (CVD) or physical vapor deposition (PVD). Other materials, such as polymers, photoresist, silicon nitride (Si₃N₄) and the like, may also be used. The significance of the sacrificial layer 35 will become apparent below.

After forming the sacrificial layer 35, a photoresist layer 36 is formed on sacrificial layer 35 and is patterned so that a first portion 351 of the sacrificial layer 35 over the PMOS area 32 is exposed, while a second portion 352 of the sacrificial layer 35 over the NMOS area 33 is protected by photoresist 36, as shown in FIG. 1.

As shown in FIG. 2, the first portion of the sacrificial layer 35 over the PMOS area 32 is removed, preferably using a wet chemical etching process. If the sacrificial oxide layer 35 is SiO₂, then an HF solution that is not debilitating to the underlying gate dielectric material 34 may be used. Note the second portion 352 of the sacrificial layer 35 on dielectric material 34 remains and covers the NMOS area 33.

With the second portion 352 of the sacrificial layer 352 in place, a PMOS gate material (PMOS gate electrode) 51 is formed on the gate dielectric material 34 over both the PMOS area 32 and the NMOS area 33, as shown in FIG. 3. Since the second portion 352 of the sacrificial layer 35 remains over the NMOS area 33, the PMOS gate material 51 is formed over the second portion 352. In one embodiment, the PMOS gate material 51 may be iridium, for example, and may have a thickness of approximately 50 to 500 Angstroms (5-50 nanometers). Other candidates for first metal gate conductor 51 include rhenium, platinum, molybdenum, ruthenium and ruthenium oxide. The PMOS gate material 51 may be formed by CVD, PVD, atomic layer deposition (ALD), metal beam epitaxy (MBE), reactive evaporation, pulsed laser deposition, the like, and combinations of the above.

After forming the PMOS gate material 51, a photoresist 61 is formed over the semiconductor substrate 31 and patterned to expose the portion of the PMOS gate material 51 that is over the NMOS area 33. The exposed portion of first gate conductor 51, over the NMOS area 33 of the first semiconductor device 25, is then subjected to a metal removal step, down to, and perhaps into, the second portion 352 of the sacrificial layer 35, as shown in FIG. 4. Removal of a portion of the PMOS gate material 51 is preferably accomplished with a dry, gaseous plasma etch. In the prior art, the plasma etch invariably attacks the underlying gate dielectric material 34. However, the second portion 352 of the sacrificial layer 35 precludes such deleterious effects and enables complete removal of exposed gate conductor material without compromising the gate dielectric material 34.

After removing a portion of the PMOS gate material 51, the second portion 352 of the sacrificial layer 35 is then etched away, with a suitable wet chemical etch, and the resist 61 is removed. As shown in FIG. 7, an NMOS gate material (NMOS gate electrode) 71 is deposited (i) over the PMOS gate material 51 (which is over the PMOS area 32) and (ii) over the dielectric material 34 that is over the NMOS area 33.

A suitable NMOS gate material 71 should have the appropriate work function to provide for a threshold voltage of approximately 4-4.3 for the NMOS gate electrode and should be able to be used in an existing CMOS process flow. Although a replacement metal gate process could be used to form a gate electrode, as opposed to that described herein, the replacement metal gate flow is more complex than a CMOS process flow (which is used herein), where the gate electrode material is formed and patterned before high temperature processes are performed. (In the replacement metal gate process a dummy gate is formed and after the high temperature processes have been performed the dummy gate is replaced with a metal that serves as the gate electrode in the transistor.) However, a suitable gate electrode material that is used in a traditional CMOS process flow needs to be able to withstand high temperatures (such as approximately 700 degrees Celsius for 60 seconds) that are used in subsequent processes. Many metal gate materials, such as platinum, can not withstand such high temperatures due to excessive diffusion into the gate dielectric.

The inventors have shown that tantalum carbide (TaC) and lanthium hexaboride (LaB₆) are suitable NMOS gate electrode materials. Both materials have work functions that are between approximately 4 and 4.3 eV and can withstand relatively high temperatures used in traditional CMOS processing. For example, TaC has been shown to have a work function of approximately 4.0 eV and 4.3 eV when hafnium oxide and silicon dioxide are used as gate insulators, respectively. In general, TaC has been shown to have a work function of 4-4.3 eV. In addition, TaC has been shown to be stable up to temperatures of approximately 900 degrees Celsius for approximately 60 seconds. While LaB₆ has been shown to not be as stable as TaC because at approximately 900 degrees Celsius boron may diffuse from the gate electrode to the substrate, LaB₆ has been shown to be stable up to approximately 800 degrees Celsius for approximately 60 seconds. LaB₆ when used with a silicon dioxide gate insulator has been found to have a work function of approximately 3.5 eV and when used in conjunction with hafnium oxide has found to have a work function of approximately 4.2 eV. Moreover, LaB₆, in general, has been shown to have a work function between approximately 3-4 eV. TaC was formed using reactive sputtering. For example, an Ar/N₂/CH₄ plasma is formed and used in conjunction with a Ta sputter target to form a TaC film. The LaB₆ films were deposited by electron beam evaporation from LaB₆ target material.

In addition, materials such as CeB₆, TaCN, and PrB₆ may be suitable as NMOS gate electrodes. Furthermore, any metal boride (MBₓ), metal carbide (MCₓ), metal carbo-nitrides (MCₓN_{y}), metal boro-carbide (MBₓC_{y}), metal boro-nitride (MBₓN_{y}) or metal boro-carbo-nitride (MBₓC_{y}N_{z}), wherein the metal is a transition metal (Group III-XII of the periodic chart) may be suitable as NMOS gate electrode materials. More specifically, the metal used in the above mentioned material may be Ta, Ti, Mo, W, Hf, Zr, La, Y, Ce, Nb, Re, the like or combinations of the above. The presence of boron or carbon in the material may tend to lower the work function of the material more than nitrogen and therefore, may be more desirable in an NMOS gate material than nitrogen.

The NMOS gate electrode may be formed using PVD (such as reactive sputtering), CVD, ALD, metal beam epitaxy (MBE), reactive evaporation, pulsed laser deposition, the like, and combinations of the above. In one embodiment, a sputter system may be outfitted with a turbo-cryo pump and methane, argon and nitrogen gas to enable reactive sputtering using argon, nitrogen, and methane. Ethane, propane or butane can be used in place of methane. In one embodiment, reactive sputtering can be used at a temperature of approximately 300 degrees Celsius.

The work function of the NMOS gate electrode can be tuned or adjusted by varying the ratio of the process gases. For example, the N₂/CH₄ ratio can be increased to increase the nitrogen as compared to carbon that is being incorporated into the gate electrode. Alternately, the N₂/CH₄ ratio can be decreased to incorporate more carbon than nitrogen into the gate electrode. Thus, TaCN may be formed by using a higher ratio of N₂/CH₄ than when forming TaC.

It should be noted that the invention has been described here with reference to a particular embodiment, according to which the first gate conductor is initially formed over the PMOS area of the CMOS transistor and second gate conductor is subsequently formed over the NMOS area. In an alternative embodiment, the first gate conductor may be formed over the NMOS area of the transistor. In this case, metal that is more closely compatible with NMOS characteristics is initially deposited. In a manner precisely analogous to the fabrication process described above, the second metal conductor is subsequently formed on the first metal conductor, over the NMOS device, and on the gate dielectric over the PMOS device. In this embodiment, the NMOS gate material 71 can be patterned in one embodiment using a plasma or wet etch processes. Regardless, in the NMOS area 33 the NMOS gate electrode should be in contact with the gate dielectric material 34 and the PMOS gate electrode should be in contact with the gate dielectric material 34 in the PMOS area because it is the gate electrode that is in contact with the gate dielectric material 34 that determines the threshold voltage of the device in that area.

In addition, further processing can be performed to complete fabrication of the PMOS and NMOS transistors in the PMOS and NMOS areas, respectively. For example, patterning processes may be performed to pattern the gate electrodes, gate dielectric material, and to form source and drain regions within the PMOS area 32 and the NMOS area, for example.

FIG. 6 illustrates a cross-sectional view of a second semiconductor device 80 that includes an NMOS transistor 92. Any materials, processes, thicknesses, etc. previously discussed can be used for the same features in the second semiconductor device 80. The NMOS transistor 92 may be used as the transistor in the aforementioned dual gate CMOS process or can be formed using a different process. After a gate dielectric material and NMOS gate material are formed over a semiconductor device 82, which can be any material previously discussed, the gate dielectric material is patterned to form a gate dielectric 86 and the NMOS gate material is patterned to form an NMOS gate electrode 88. The patterning may be performed by forming and patterning a photoresist over the NMOS gate material and using a dry plasma etch process to etch the NMOS gate material. For example, a fluorine based chemistry, such as CF₄, can be used in conjunction with argon to form the plasma used to etch the NMOS gate material when it is TaC or LaB₆, for example. A suitable chemistry known to those skilled in the art can be used to etch the gate dielectric material using a dry plasma etch or another suitable process.

After the gate dielectric 86 and the NMOS gate electrode 88 are formed, an ion implantation process may be performed to form part of the current electrode regions 84, such as the extension regions (not illustrated with a separate number). The current electrode regions, in one embodiment are the source and drain regions of the NMOS transistor 92 and may include extension regions, halo regions, etc. After forming the extensions, spacers 90 may be formed. In one embodiment, the spacers 90 are formed by depositing a nitride film, such as silicon nitride, and anisotropically etching the nitride film. After the spacers 90 are formed, another ion implantation process may be performed to form a heavily-doped region as part of the current electrode regions 84. Additionally, halo implantation processes could be used. All dopants used will be n-type in order to form the NMOS transistor 92.

If the NMOS transistor 92 in FIG. 6 is being formed on a portion of a semiconductor device, during the implantation process(es) used to form the current electrodes 84, portions of the semiconductor substrate 82 where n-type dopants are not desired to be formed will need to be masked off. In one embodiment, a patterned photoresist layer can be used. Furthermore, portions of or the entire NMOS transistor 92 may need to be covered by photoresist when p-type dopants are being implanted to form PMOS transistors in other portions of the semiconductor substrate 82.

After forming the NMOS transistor an interlevel dielectric (ILD) 94 is formed over the NMOS transistor 92. In one embodiment, the ILD is silicon dioxide or fluorinated silicon dioxide formed using tetraethylorthosilane (TEOS). Any dielectric material may be used as the ILD 94, especially a low k material, which is a material with a k less than silicon dioxide. Any suitable process may be used, such as CVD or PVD. As shown in FIG. 6, the ILD 94 is in contact with (at least a portion of) the NMOS gate electrode 88.

Openings are formed within the ILD 94 using known patterning and etch processes. The openings are then filled with a conductive material, such as a metal, to form a first via 97 and a second via 95. Any conventional process may be used. The metal may be W, Al, Cu the like and combinations of the above. The first via 97 is coupled to the current electrode 84 and the second via 95 is coupled to the NMOS gate electrode 88.

After forming the first via 97 and the second via 95, processing continues as known to one skilled in the art. Details are not explained as it is not important to understanding the current invention.

By now it should be appreciated that there has been provided an NMOS gate electrode that meets the desired voltage requirements. The materials may be used in conjunction with high dielectric constant materials used as gate dielectrics. Furthermore, the processes described can be used to form an NMOS transistor alone or in conjunction with a PMOS transistor. Other processes may also be used. For example, thin, “zero spacers”, preferably of silicon nitride, may be formed immediately adjacent the patterned gate structures in each of the PMOS and NMOS transistors. The extension implants, and halo implants if used, are then performed. The zero spacers protect the sides of the gate structure during removal of the photoresist mask used to mask the implants. A capping layer may also be used in conjunction with the zero spacers. In one embodiment, the capping layer may be polysilicon.

In the foregoing specification, the invention has been described with reference to specific embodiments. However, one of ordinary skill in the art appreciates that various modifications and changes can be made without departing from the scope of the present invention as set forth in the claims below. For example, other dual-gate processes can be used to form the NMOS and PMOS transistors. Additionally, different processes can be used to form an NMOS transistor than those described. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms “a” or “an”, as used herein, are defined as one or more than one. Moreover, the terms “front”, “back”, “top”, “bottom”, “over”, “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

1. A method of forming a semiconductor device, the method comprising:
providing a semiconductor substrate;
forming a gate dielectric material over the semiconductor substrate;
depositing a gate electrode material over the gate dielectric material, wherein the gate electrode material comprises a transition metal and an element selected from the group consisting of boron and carbon;
patterning the gate dielectric material to form a gate dielectric;
patterning the gate electrode material to form a gate electrode, wherein the gate electrode consists of the gate electrode material; and
forming current electrodes within the semiconductor substrate and laterally adjacent the gate dielectric.

2. The method of claim 1, wherein depositing the gate electrode material is performed by physical vapor deposition.

3. The method of claim 2, wherein depositing the gate electrode material is performed by reactive sputtering.

4. The method of claim 2, wherein depositing the gate electrode further comprises: providing a target material, wherein the target material comprises the transition metal; and flowing a process gas, wherein the process gas comprises carbon and nitrogen.

5. The method of claim 4, wherein the process gas comprises a gas selected from the group consisting of methane, ethane, propane and butane.

6. The method of claim 1, wherein the gate electrode material further comprises nitrogen.

7. The method of claim 1, wherein the gate electrode material comprises boron and carbon.

8. The method of claim 7, wherein the gate electrode material comprises nitrogen.

9. The method of claim 1, wherein forming the current electrodes are performed after forming the gate electrode.

10. The method of claim 1, further comprising exposing the gate electrode to temperature greater than approximately 700 degrees Celsius.

11. The method of claim 1, wherein forming the current electrodes comprises forming n-type regions.

12. The method of claim 1, wherein depositing the gate electrode material further comprises depositing a material selected from the group consisting of TaC, LaB₆, CeB₆, and PrB₆.

13. The method of claim 1, wherein depositing the gate electrode material further comprises depositing a material selected from the group consisting of metal carbides, metal borides, metal boro-carbides, metal boro-nitrides, metal carbo-nitrides and metal boro-carbo-nitrides.

14. A method of forming a semiconductor device, the method comprising:
providing a semiconductor substrate;
forming a gate dielectric material over the semiconductor substrate;
depositing a gate electrode material over the gate dielectric material, wherein the gate electrode material comprises a transition metal and an element selected from the group consisting of boron and carbon;
patterning the gate dielectric material to form a gate dielectric;
patterning the gate electrode material to form a gate electrode;
forming current electrodes within the semiconductor substrate and laterally adjacent the gate dielectric; and
forming a dielectric layer (94) over and in contact with the gate electrode.

15. The method of claim 14, wherein depositing the gate electrode material is performed by physical vapor deposition.

16. The method of claim 15, wherein depositing the gate electrode material is performed by reactive sputtering.

17. The method of claim 15, wherein depositing the gate electrode further comprises: providing a target material, wherein the target material comprises the transition metal; and flowing a process gas, wherein the process gas comprises carbon and nitrogen.

18. The method of claim 17, wherein the process gas comprises a gas selected from the group consisting of methane, ethane, propane and butane.

19. The method of claim 14, wherein the gate electrode material further comprises nitrogen.

20. The method of claim 14, wherein the gate electrode material comprises boron and carbon.

21. The method of claim 20, wherein the gate electrode material comprises nitrogen.

22. The method of claim 14, wherein forming the current electrodes are performed after forming the gate electrode.

23. The method of claim 14, further comprising exposing the gate electrode to temperature greater than approximately 700 degrees Celsius.

24. The method of claim 14, wherein forming the current electrodes comprises forming n-type regions.

25. The method of claim 14, wherein depositing the gate electrode material further comprises depositing a material selected from the group consisting of TaC, LaB₆, CeB₆, and PrB₆.

26. The method of claim 14, wherein depositing the gate electrode material further comprises depositing a material selected from the group consisting of metal carbides, metal borides, metal boro-carbides, metal boro-nitrides, metal carbo-nitrides and metal boro-carbo-nitrides.

27. A semiconductor device comprising:
a semiconductor substrate;
a gate dielectric over the semiconductor substrate;
a gate electrode over the gate dielectric material, wherein the gate electrode material comprises a transition metal and an element selected from the group consisting of boron and carbon;
current electrodes within the semiconductor substrate and laterally adjacent the gate dielectric; and
a dielectric layer (94) over and in contact with the gate electrode.

28. The method of claim 1, wherein the gate electrode material further comprises nitrogen.

29. The method of claim 14, wherein depositing the gate electrode material further comprises depositing a material selected from the group consisting of metal carbides, metal borides, metal boro-carbides, metal boro-nitrides, metal carbo-nitrides and metal boro-carbo-nitrides.

30. The method of claim 14, wherein depositing the gate electrode material further comprises depositing a material selected from the group consisting of TaC, LaB₆, CeB₆, and PrB.

31. The semiconductor device of claim 27, wherein the gate electrode is a gate electrode for a NMOS transistor.

32. A method for forming a semiconductor device, the method comprising:
providing a semiconductor substrate;
forming a gate dielectric material over the semiconductor substrate;
forming a gate electrode material having a predetermined work function comprising:
flowing a precursor, wherein the precursor comprises nitrogen and carbon;
adjusting a ratio of nitrogen to carbon in while flowing the precursor to achieve the predetermined work function;
patterning the gate dielectric material to form a gate dielectric;
patterning the gate electrode material to form a gate electrode;
forming current electrodes within the semiconductor substrate and laterally adjacent the gate dielectric; and
forming a dielectric layer over and in contact with the gate electrode.

33. The method of claim 32, wherein adjusting the ratio of nitrogen to carbon further comprises decreasing the ratio of nitrogen to carbon.
